(19) United States
(12) Patent Application Publication
(10) Pub. No.: US 2016/0020309 A1
(43) Pub. Date: Jan. 21, 2016

(54) SEMICONDUCTOR DEVICE AND POWER CONVERSION DEVICE USING SAME

(71) Applicant: HITACHI POWER SEMICONDUCTOR DEVICE, LTD., Hitachi-shi, Ibaraki (JP)

(72) Inventors: Hiroshi Suzuki, Tokyo (JP); Masaki Shiraishi, Tokyo (JP); So Watanabe, Tokyo (JP); Tetsuya Ishimaru, Tokyo (JP)

(21) Appl. No.: 14/649,537

(22) PCT Filed: Dec. 3, 2013
(86) PCT No.: PCT/JP2013/082431

§ 371 Date: Jun. 3, 2015

(30) Foreign Application Priority Data
Dec. 5, 2012 (JP) 2012-265905

(51) Int. Cl. H01L 29/739; H02M 7/5387

(52) U.S. Cl. CPC H01L 29/7397; H02M 7/5387

(57) ABSTRACT

The problem addressed by the present invention is to provide a semiconductor device capable of improving dv/dt controllability via a gate drive circuit during turn-on switching. The semiconductor device comprises a plurality of trench gate groups, each trench gate group including mutually adjoining three or more trench gates, and the distance between adjoining two trench gate groups is larger than the distance between adjoining two trench gates in one trench gate group. Thereby, gate-emitter capacity increases, and therefore the semiconductor device may improve dv/dt controllability via a gate drive circuit during turn-on switching.

### TECHNICAL FIELD

The present invention relates to a semiconductor device and a power conversion device using the same. More specifically, it relates to a semiconductor device that is suitable for an Insulated Gate Bipolar Transistor (which, hereinafter, will be referred to as “IGBT”), and a power conversion device using the semiconductor device.

### BACKGROUND ART

The IGBT is a switching element in which a current flowing between the collector electrode and the emitter electrode is controlled by a voltage that is applied to the gate electrode. The power that can be controlled by the IGBT ranges from a few tens of watts to a few hundred thousands of watts. Also, its switching frequency ranges from a few tens of hertz to one hundred kilohertz or higher, which is also significantly wide. Accordingly, the IGBT is used significantly widely, i.e., from small-power appliances such as home-use air conditioner and microwave oven to large-power appliances such as inverter of railroad and steelmaking plant.

The low-loss implementation of the IGBT is requested for the purpose of the high-efficiency implementation of these power appliances. Namely, the IGBT is requested to exhibit reductions in its conduction loss and switching loss. Simultaneously, in order to prevent problems such as EMC noise, malfunction, motor's breakdown, the IGBT is requested to be able to control its output voltage's time change rate dv/dt in accordance with the specification of an application

By the way, in PATENT LITERATURE 1 (JP-A-2000-307116), there is disclosed an IGBT of the structure where, as is illustrated in FIG. 10, the arrangement spacing between trench gates is changed. The feature of the IGBT illustrated in FIG. 10 is the following point: In a location where the spacing between the trench gates is wide, a p channel layer 106 is not formed, but a floating p layer 105 is set up instead.

The employment of the configuration like this causes the current to flow only through portions where the spacing between the trench gates is narrow. This makes it possible to suppress an overcurrent that will flow at the time of short-circuit, thereby allowing an enhancement in the device's breakdown tolerance capacity. Also, a partial component of the hole current flows into the p channel layer 106 via the floating p layer 105. This increases the hole concentration in proximity to each trench gate, thereby making it possible to reduce the on-state voltage. Moreover, a pn junction that is formed by the floating p layer 105 and an n⁻ drift layer 104 relaxes an electric field applied to each trench gate, thereby making it possible to hold the withstand voltage.

### CITATION LIST

### Patent Literature

Patent Literature 1: JP-A-2000-307116 (FIG. 16)

### SUMMARY OF INVENTION

### Technical Problem

In the IGBT illustrated in FIG. 10, however, the following problem occurs in some cases: At the turn-on time of the IGBT, the controllability of dv/dt of a diode connected to the IGBT and pair arms becomes lowered.

It is conceivable that the reason for this occurrence is as follows: When a voltage higher than a threshold voltage is applied to the gate electrode to inject electrons, holes are injected from the rear surface, and a part of the holes flows through the floating p layer 105. This raises the electric potential y_{f} of the floating p layer. At this time, the holes existing in the floating p layer 105 charge the inter-gate-collector capacity Cgc, thereby lifting up the gate voltage (ΔVge). This results in self-acceleration of the turn-on, which then generates a large dv/dt in the diode connected to the IGBT in pairs. This ΔVge depends on the capacity ratio Cgc/Cge between the inter-gate-collector capacity Cgc and the inter-gate-emitter capacity Cge Accordingly, a reduction in Cgc/Cge or elimination of the floating p layer 105 is effective for implementing an enhancement in the controllability of dv/dt by the gate resistance. However, since this capacity ratio is determined by the device structure, it is difficult to control dv/dt only by adjusting an external factor (such as the gate resistance). As a result of this, the controllability of dv/dt by the gate resistance becomes lowered

During the transient time-period at this turn-on's initial stage, the electric-charge amount ΔQsw with which the holes in the floating p layer 105 charge the gate electrode is represented by the following Expression (1).

$$\begin{matrix}[ Expression 1 ] & \\ Δ {Q}_{sw} = {\int }_{sw} {C}_{gc} \frac{d {v}_{f}}{d t} d t & ( 1 )\end{matrix}$$

This ΔQsw lifts up the gate voltage by the amount of ΔVge via the inter-gate-emitter capacity Cge. Consequently, ΔQsw can also be represented by the following Expression (2).

[Expression 2]

ΔQ_{sw}=C_{gc}ΔV_{gc} (2)

Based on Expression (1) and Expression (2), the lift-up amount ΔVge of the gate voltage is represented by the following Expression (3)

$$\begin{matrix}[ Expression 3 ] & \\ Δ {V}_{ge} = \frac{{C}_{gc}}{{C}_{ge}} {\int }_{sw} \frac{d {v}_{f}}{d t} d t & ( 3 )\end{matrix}$$

The present invention has been devised in view of the above-described point. Namely, an object of the present invention is to provide a semiconductor device that allows the implementation of an enhancement in the controllability of dv/dt by the gate driving circuit during the turn-on switching time-period, and a power conversion device using the semiconductor device.

### Solution to Problem

In the semiconductor device according to the present invention, there are provided a plurality of trench-gate groups, each of which includes mutually-adjoining three or more trench gates. Here, the spacing between mutually-adjoining two trench-gate groups is wider than the spacing between mutually-adjoining two trench gates in one trench-gate group. This increases the inter-gate-emitter capacity, thereby allowing the implementation of an enhancement in the controllability of dv/dt by the gate driving circuit during the turn-on switching time-period. Accordingly, it becomes possible to reduce the power loss or noise caused to occur by the semiconductor device. Consequently, applying the semiconductor device according to the present invention to a power conversion device makes it possible to accomplish the low-loss implementation or high-reliability implementation of the power conversion device.

Also, the semiconductor device in one aspect of the present invention includes a first semiconductor layer of first conduction type, a second semiconductor layer of second conduction type, the second semiconductor layer adjoining to the first semiconductor layer, a plurality of third semiconductor layers of the first conduction type, the third semiconductor layers adjoining to the second semiconductor layer, a plurality of fourth semiconductor layers of the second conduction type, the fourth semiconductor layers being provided on the surfaces of the third semiconductor layers, a plurality of trench gates provided inside a plurality of trenches, the side walls of the trenches being the surfaces of the third semiconductor layers, a first main electrode electrically connected to the first semiconductor layer, and a second main electrode electrically connected to the plurality of third semiconductor layers and the plurality of fourth semiconductor layers. Moreover, the semiconductor device includes a plurality of trench-gate groups, each of the trench-gate groups including the three or more trench gates that adjoin to each other, the spacing between the two trench-gate groups that adjoin to each other being wider than the spacing between the two trench gates that adjoin to each other in the one trench-gate group.

Here, the first conduction type and the second conduction type are, for example, p type and n type, respectively. Also, the first semiconductor layer, the second semiconductor layer, the third semiconductor layers, the fourth semiconductor layers, the first main electrode, and the second main electrode are, for example, a p-type collector layer, an n-type semiconductor layer formed of an n-type buffer layer and an n-type drift layer, p-type channel layers, n-type emitter layers, a collector electrode, and an emitter electrode, respectively Incidentally, the first conduction type and the second conduction type may also be n type and p type, respectively.

### Advantageous Effects of Invention

The semiconductor device according to the present invention allows the implementation of an enhancement in the controllability of dv/dt by the gate driving circuit. Furthermore, applying the semiconductor device according to the present invention to a power conversion device makes it possible to accomplish the low-loss implementation or high-reliability implementation of the power conversion device.

The other objects, features and advantages of the present invention will become apparent from the following description of embodiments of the present invention associated with the accompanying drawings.

### BRIEF DESCRIPTION OF DRAWINGS

FIG. 1 illustrates the longitudinal-direction cross section of an IGBT which is a first embodiment of the present invention.

FIG. 2 illustrates the relationship between the recovery dv/dt of a diode connected to the IGBT in pairs, and the gate resistance.

FIG. 3 illustrates fabrication steps of the IGBT in the first embodiment.

FIG. 4 illustrates the longitudinal-direction cross section of an IGBT which is a modified example of the first embodiment.

FIG. 5 illustrates the longitudinal-direction cross section of an IGBT which is a second embodiment of the present invention.

FIG. 6 illustrates the longitudinal-direction cross section of an IGBT which is a third embodiment of the present invention.

FIG. 7 illustrates the longitudinal-direction cross section of an IGBT which is a fourth embodiment of the present invention.

FIG. 8 illustrates the longitudinal-direction cross section of an IGBT which is a fifth embodiment of the present invention.

FIG. 9 illustrates a power conversion device where the IGBTs according to the present invention are used.

FIG. 10 illustrates the longitudinal-direction cross section of the IGBT in the prior art

FIG. 11 illustrates the relationship between the controllability of dv/dt and the switching loss.

### DESCRIPTION OF EMBODIMENTS

Hereinafter, based on embodiments illustrated, the detailed explanation will be given below concerning a semiconductor device according to the present invention.

### Embodiment 1

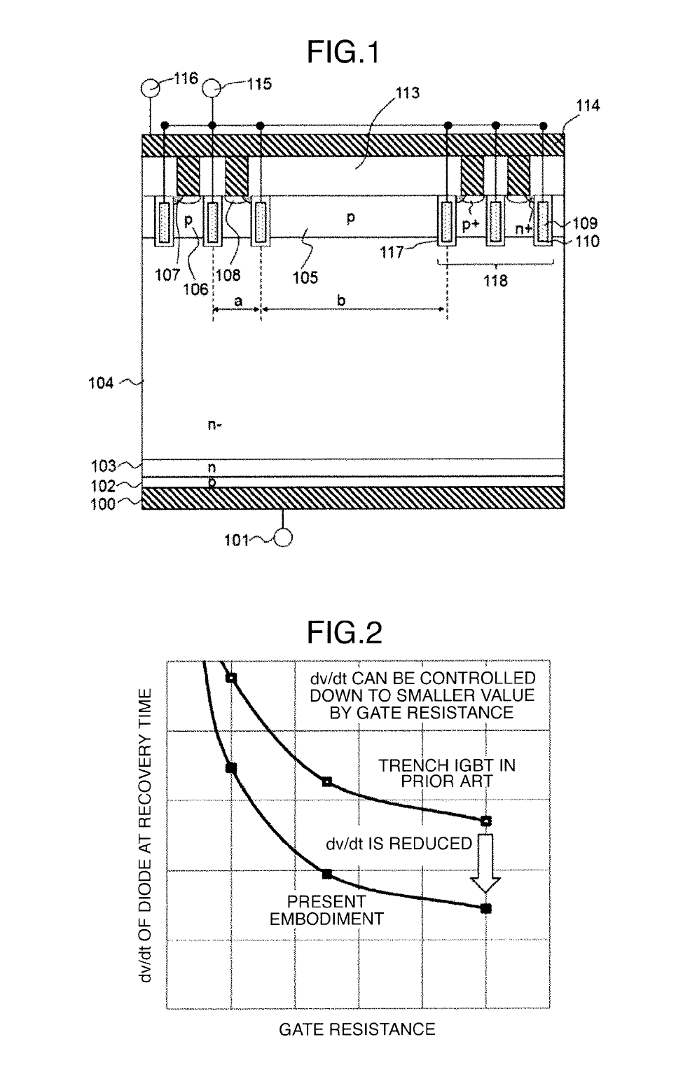

FIG. 1 illustrates the longitudinal-direction cross section of an IGBT which is a first embodiment of the present invention. In the embodiments hereinafter, “p” and “n” indicate the conduction types of a semiconductor layer, and indicate p type and n type, respectively Also, n⁻, n, n⁺ indicates that n-type impurity concentrations become higher in this sequence. Incidentally, the large-or-small relationship of p-type impurity concentrations is also designated similarly.

In the present embodiment, a p collector layer 102 adjoins to an n-type semiconductor layer in the longitudinal direction. Here, this n-type semiconductor layer is formed of an n buffer layer 103 whose impurity concentration is lower than that of the p collector layer 102, and the n⁻ drift layer 104 whose impurity concentration is lower than that of the n buffer layer 103. The p collector layer 102 and the n buffer layer 103 forms a pn junction, and the n buffer layer 103 and the n⁻ drift layer 104 are jointed to form the n-type semiconductor layer. When the present IGBT is in a voltage-blocked state, the voltage is blocked in such a manner that a depletion layer spreads in the n⁺ drift layer 104 mainly.

The p channel layer 106 and the floating p layer 105, whose impurity concentrations are higher than that of the n⁻ drift layer 104, adjoin to the n⁻ drift layer 104. A pn junction is formed between each of the p channel layer 106 and the floating p layer 105, and the n⁻ drift layer 104. Incidentally, the depth of the p channel layer 106 and the depth of the floating p layer 105 are equal to each other, but the width of the floating p layer 105 is wider than the width of the p channel layer 106. An n⁺ emitter layer 107 and a p⁺ contact layer 108, whose impurity concentrations are higher than that of the p channel layer 106, are provided within the p channel layer 106.

The IGBT in the present embodiment has an operation area 118 that includes a p-channel-layer group and a trench-gate group Here, the p-channel-layer group is formed of the two p channel layers 106 that adjoin to each other in the transverse direction. The trench-gate group is formed of three trench gates 117 that adjoin to each other in the transverse direction similarly. A main current flows through the operation area 118. The area including one p-channel-layer group and one floating p layer 105 that adjoins to this one p-channel-layer group becomes one unit of the IGBT.

The three trench gates 117 included in one trench-gate group are provided among both end portions of the p-channel-layer group and the two p channel layers 106 that adjoin to each other in the p-channel-layer group. Namely, in the operation area 118, the three trench gates 117 in the trench-gate group and the two p channel layers 106 in the p-channel-layer group are provided in a manner of being arranged alternately in the transverse direction.

Incidentally, as described above, the width of the floating p layer 105 is wider than the width of the p channel layer 106. As a result, the spacing b between the two trench-gate groups that are provided on both sides of one floating p layer 105 and that adjoin to each other in the transverse direction is wider than the spacing a between the two trench gates 117 that adjoin to each other in the transverse direction within the one trench-gate group.

A collector electrode 100 is electrically connected to the p collector layer 102 by the Ohmic contact. Also, an emitter electrode 114 is electrically connected to the n⁺ emitter layer 107 by the Ohmic contact. The emitter electrode 114 is in the Ohmic contact with the p⁺ contact layer 108 as well. This causes the emitter electrode 114 to be electrically connected to the p⁺ contact layer 108 and the p channel layer 106. Here, the emitter electrode 114 and the floating p layer 105 are electrically separated from each other by an inter-layer insulating film 113.

Also, in each trench gate 117, a gate insulating film 110 is provided between a gate electrode 109, which is provided within a trench groove whose side wall is the vertical surface of the p channel layer 106, and each surface of the n⁺ emitter layer 107, the p channel layer 106, and the n⁻ drift layer 104 within the trench groove. These gate electrode 109 and gate insulating film 110 constitute each trench gate 117, which becomes the MOS gate electrode, i.e., the insulated gate electrode. The gate electrode 109 and the emitter electrode 114 are electrically separated from each other by the inter-layer insulating film 113 within the IGBT.

The collector electrode 100, the emitter electrode 114, and the gate electrode 109 are electrically connected to a collector terminal 101, an emitter terminal 116, and a gate terminal 115, respectively.

Incidentally, the above-described n⁺ emitter layer 107 is provided on the surface of each p channel layer 106 which, in one trench-gate group, adjoins to each trench gate 117 at the right and left ends in FIG. 1, and which is opposed to the gate electrode 109 therein.

In the present embodiment, there are provided the trench-gate groups, each of which includes the three trench gates 117 that adjoin to each other in the transverse direction. This configuration increases the inter-gate-emitter capacity Cge. Incidentally, the number of the trench gates 117 included in one trench-gate group can be set at three or more, depending on desired characteristics of the IGBT.

FIG. 2 illustrates the result that the present inventor has obtained by checking the relationship between the recovery dv/dt of a diode connected to the IGBT in pairs, and the gate resistance with respect to the IGBT in the present embodiment and the trench IGBT in the prior art. As illustrated in FIG. 2, the IGBT in the present embodiment makes it possible to control the recovery dv/dt down to a value that is smaller than the case of the IGBT in the prior art.

Also, in the present embodiment, the spacing b between the two trench-gate groups that adjoin to each other in the transverse direction is wider than the spacing a between the two trench gates 117 that adjoin to each other in the transverse direction within the one trench-gate group. Simultaneously, the n⁻ emitter layer 107 is provided on the surface of each p channel layer 106 which is opposed to each trench gate 117 at both ends of one trench-gate group. This situation causes a partial component of the hole current to flow into each p channel layer 106 via the floating p layer 105 and a proximity to each trench gate 117 at both ends of the one trench-gate group. This flow-in of the hole current, further, promotes the injection of electrons, thereby making it possible to reduce the on-state voltage. Here, the n⁻ emitter layer 107 is provided on the surface of each p channel layer 106 which is the closest to the floating p layer 105. This situation enhances the electron-injection promotion effect exerted by the hole current that flows into the floating p layer 105.

Incidentally, in the present embodiment, the n⁺ emitter layer 107 is provided on only the surface of each p channel layer 106 which, in one trench-gate group, is opposed to each trench gate 117 at both ends of the one trench-gate group. The n⁻ emitter layer 107, however, may also be provided on each p channel layer 106 which is opposed to each trench gate 117 at the central position of the one trench-gate group. This increases a saturated current, thereby making it possible to reduce the on-state voltage. Also, in the present embodiment, the pn junction formed by the floating p layer 105 and the n⁻ drift layer 104 relaxes the electric field applied to each trench gate, thereby enhancing the withstand voltage of the IGBT.

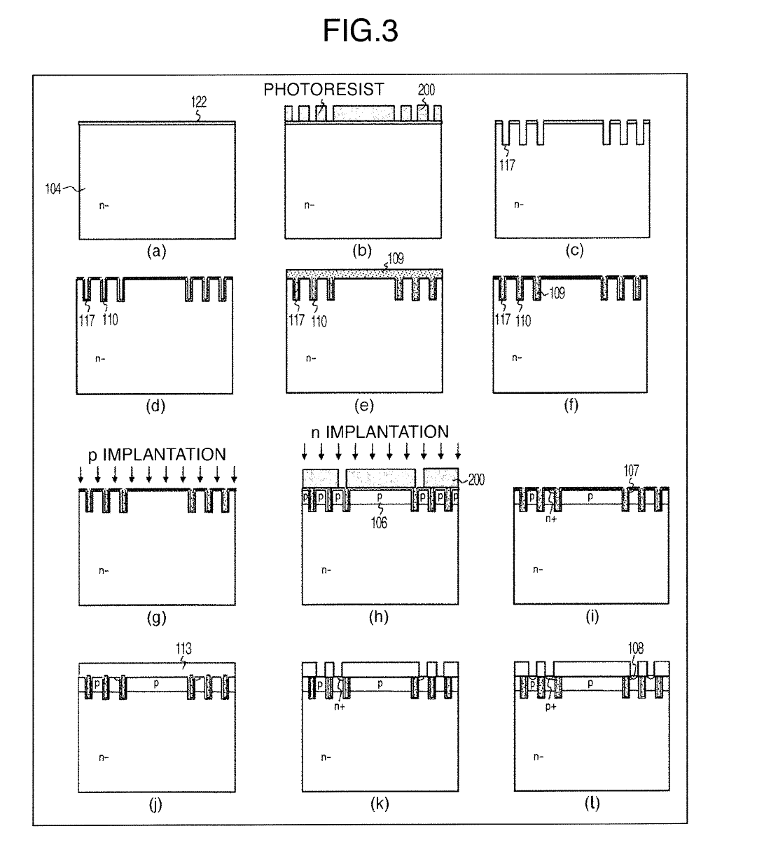

FIG. 3(a)-(l) illustrate an example of fabrication steps of the IGBT illustrated in FIG. 1

First of all, as illustrated in FIG. 3(a), an oxide film 122 is formed by thermal oxidation or the like on the surface of an n-type semiconductor substrate that becomes the n⁻ drift layer 104. Next, as illustrated in FIG. 3(b), patterning of photoresist 200 is performed. Next, as illustrated in FIG. 3(c), the trench grooves for forming the trench gates 117 are formed by etching. Incidentally, in FIG. 3, the reference numeral 117 is affixed onto the areas that become the trench gates 117 eventually.

Next, as illustrated in FIG. 3(d), the gate insulating films 110 are formed. Next, as illustrated in FIG. 3(e), polysilicon that becomes the gate electrodes 109 is deposited. Next, as illustrated in FIG. 3(f), the trench-gate groups are formed by etching the polysilicon using a dry etching method or wet etching method.

Next, as illustrated in FIG. 3(g), p-type ions are implanted into the entire surface of the semiconductor substrate. Moreover, as illustrated in FIG. 3(h), after the patterning of the photoresist 200 is performed, n-type ions are implanted into the entire surface, thereby forming the p channel layers 106, the floating p layer 105, and the n⁺ emitter layers 107. Next, as illustrated in FIG. 3(j), the inter-layer insulating film 113 is deposited. Next, as illustrated in FIG. 3(k), contact windows are bored in the inter-layer insulating film 113, and, as illustrated in FIG. 3(l), the p⁺ contact layers 108 are formed.

Furthermore, as illustrated in FIG. 1 described earlier, the emitter electrode 114, the n buffer layer 103, the p collector layer 102, and the collector electrode 100 are formed sequentially, thereby fabricating the IGBT.

Incidentally, in the fabrication method illustrated in FIG. 3, the p collector layer 102 and the n buffer layer 103 on the rear surface are formed after the surface steps at which the p channel layers 106, the floating p layer 105, the trench gates 117, and the like are formed. It is also allowable, however, to use a semiconductor substrate on which the p collector layer 102 and the n buffer layer 103 are formed in advance.

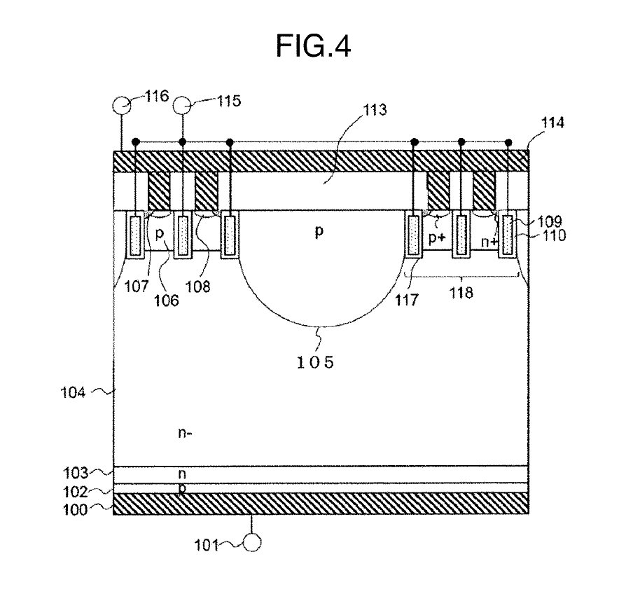

FIG. 4 illustrates the longitudinal-direction cross section of an IGBT which is a modified example of the embodiment illustrated in FIG. 1. In the present embodiment, unlike the embodiment illustrated in FIG. 1, the floating p layer 105 is formed up to an area that is deeper than bottom portions of the trench grooves in the n⁻ drift layer 104. Namely, the floating p layer 105 is formed more deeply than the p channel layers 106. This makes it possible to relax the electric-field intensities at the corners of each trench gate, thereby enhancing the withstand voltage of the IGBT.

As having been described so far, in the IGBT in the embodiment illustrated in FIG. 1 and the modified example of this IGBT, there are provided the trench-gate groups, each of which includes the three or more trench gates. This increases the inter-gate-emitter capacity Cge, thereby allowing the implementation of an enhancement in the controllability of dv/dt by the gate driving circuit during the turn-on switching time-period. Also, the spacing between the trench-gate groups is made wider than the spacing between the trench gates within the one trench-gate group. Simultaneously, the n⁻ emitter layer is provided on the surface of each p channel layer opposed to each trench gate at both ends of one trench-gate group. This makes it possible to reduce the on-state voltage. Moreover, the floating p layer is provided between the trench-gate groups that adjoin to each other. This makes it possible to enhance the withstand voltage.

FIG. 11 illustrates the result that the present inventor has obtained by checking the relationship between the dv/dt controllability and the switching loss (=turn-on loss+recovery loss) with respect to the trench IGBT in the prior art, and the present embodiment or the present modified example. According to the present embodiment and its modified example, it becomes possible to enhance the trade-off of dv/dt, and to accomplish the compatibility between the low-loss implementation and the low-noise implementation.

Incidentally, the relationships illustrated in FIG. 2 and FIG. 11 are also basically the same in respective embodiments that will be explained hereinafter.

### Embodiment 2

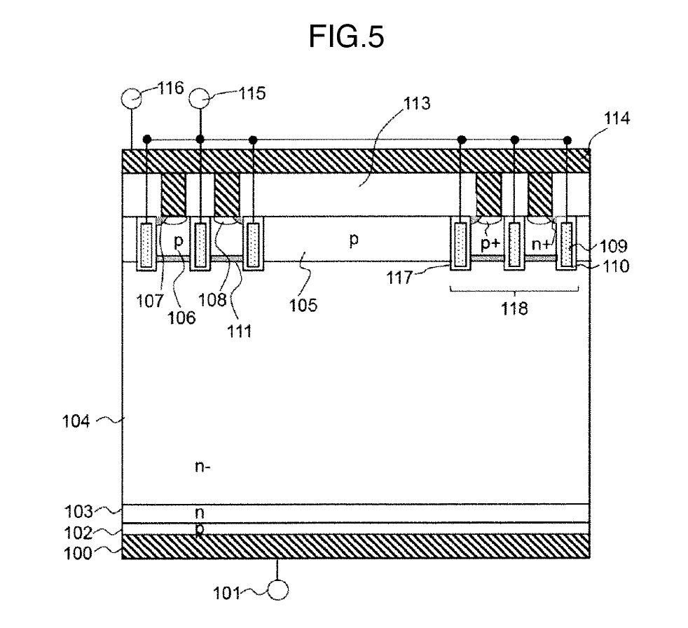

FIG. 5 illustrates the longitudinal-direction cross section of an IGBT which is a second embodiment of the present invention. In the present second embodiment, unlike the first embodiment and its modified example, an n layer 111 is provided between the p channel layer 106 and the n⁻ drift layer 104. The n layer 111 is joined to each of the p channel layer 106 and the n⁻ drift layer 104. Simultaneously, the impurity concentration of the n layer 111 is lower than that of the p channel layer 106, and is higher than that of the n⁻ drift layer 104. This n layer 111 becomes a barrier wall against the holes that will flow into the emitter electrode 114. This increases the hole concentration in the n⁻ drift layer 104 in proximity to the p channel layer 106, thereby reducing the on-state voltage.

### Embodiment 3

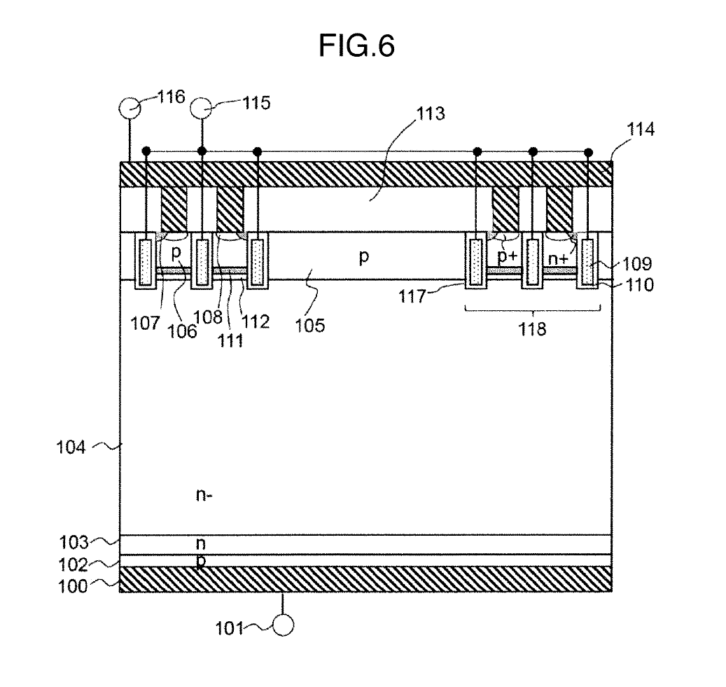

FIG. 6 illustrates the longitudinal-direction cross section of an IGBT which is a third embodiment of the present invention. In the present third embodiment, in addition to the n layer 111 provided in the second embodiment, a p layer 112 is provided between the n layer 111 and the n⁻ drift layer 104. The n layer 111 forms a pn junction with each of the p channel layer 106 and the p layer 112. Also, a pn junction is formed by the p layer 112 and the n⁻ drift layer 104. According to the present third embodiment, the p layer 112 is provided between the n layer 111 and the n⁻ drift layer 104. This relaxes the electric-field intensity in the n layer 111 in the voltage-blocked state. As a result, even when the n layer 111 is provided whose impurity concentration is higher than that of the n⁻ drift layer 104, the desired withstand voltage can be ensured.

### Embodiment 4

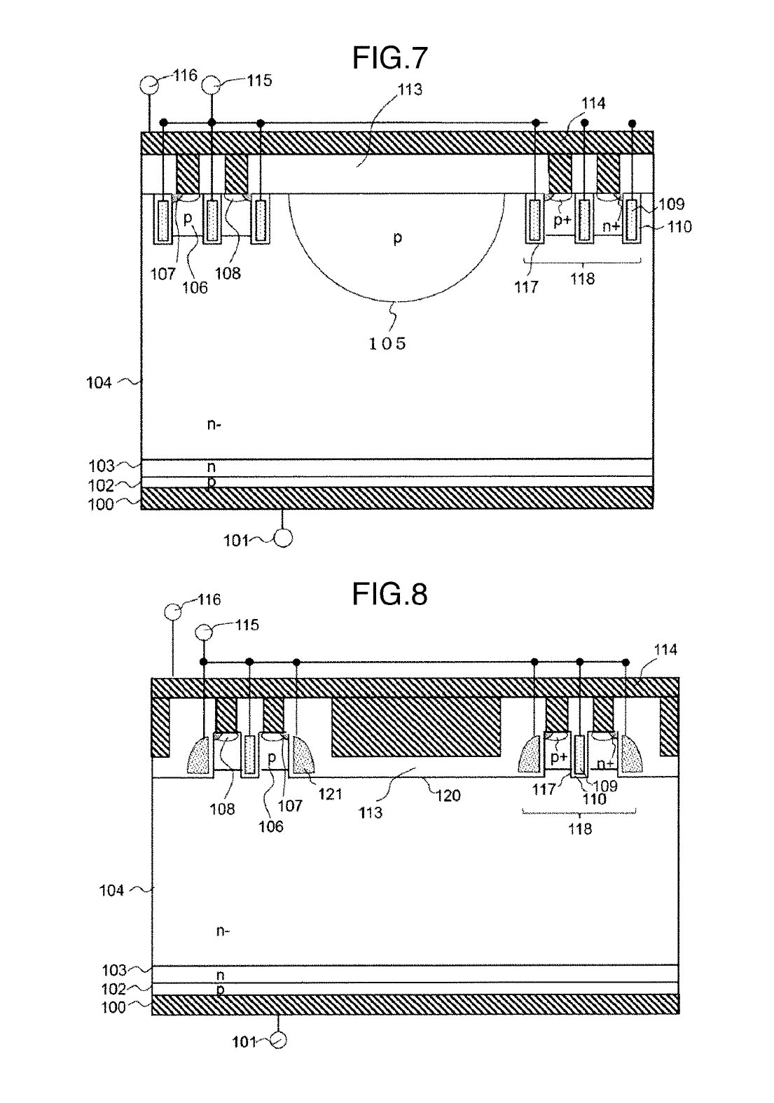

FIG. 7 illustrates the longitudinal-direction cross section of an IGBT which is a fourth embodiment of the present invention. In the present fourth embodiment, like the modified example illustrated in FIG. 4, the floating p layer 105 that is deeper than the bottom portions of the trench grooves is provided between the trench-gate groups that adjoin to each other. Moreover, unlike the modified example illustrated in FIG. 4, a partial portion of the n⁻ drift layer 104 intervenes between the floating p layer 105 and the trench gate 117 that adjoins thereto in a manner of extending onto the side of the emitter electrode 114. Namely, the floating p layer 105 and the trench gate 117 that adjoins thereto are isolated from each other without being in contact with each other by the partial portion of the n⁻ drift layer 104.

This situation makes it possible to suppress an effect that the holes, which transiently flow into the floating p layer 105 at the turn-on time, will lift up the gate voltage. The suppression of this effect allows the implementation of an enhancement in the controllability of dv/dt by the gate driving circuit. Also, the floating p layer 105 is formed in the manner of being made deeper than the bottom portions of the trench grooves. As a result, even if the floating p layer 105 is separated from the trench gate 117, it becomes possible to relax the electric-field concentrations at the corners of the trench gate 117. Accordingly, the desired withstand voltage can be ensured.

### Embodiment 5

FIG. 8 illustrates the longitudinal-direction cross section of an IGBT which is a fifth embodiment of the present invention. In the present fifth embodiment, unlike the respective embodiments and modified example described earlier, the floating p layer 105 is not formed between the trench-gate groups that adjoin to each other. Instead, there is provided a trench groove 120 whose width is wider than the width of the trench groove at the central position of the trench-gate group. Of both-ends portions of the two trench-gate groups that adjoin to each other in the transverse direction, the surface of the p channel layer 106 and the surface of the n⁻ drift layer 104 at the one-end portion positioned on the side of the trench groove 120 become one of the side walls of the trench groove 120. Also, the surface of then n⁻ drift layer 104, which is exposed between the side walls opposed to each other, becomes the bottom portion of the trench groove 120. Here, concerning the relationship between the spacing (b) between the two trench-gate groups that adjoin to each other in the transverse direction and the spacing (a) between the two trench gates that adjoin to each other in the transverse direction within the one trench-gate group, this relationship is given as being b>a as is the case with the respective embodiments and modified example described earlier.

Furthermore, in the present fifth embodiment, unlike the respective embodiments and modified example described earlier, the gate electrodes at both ends of one trench-gate group are formed using side-wall gate electrodes 121. Here, the side-wall gate electrodes 121 are opposed within the wider-width trench groove 120 to the surfaces of the p channel layers 106 that become the side walls of the trench groove 120.

In the present fifth embodiment, the trench-groove inner side of each side-wall gate electrode 121 is covered with the inter-layer insulating film 113 that is thicker than the gate insulating film 110. This makes it possible to reduce the inter-gate-collector feedback capacity Cgc, thereby allowing the implementation of an enhancement in the dv/dt controllability. Also, in the present fifth embodiment, the emitter electrode 114 and the side-wall gate electrode 121 can be caused to come closer to each other via the inter-layer insulating film 113. Accordingly, the withstand voltage can be ensured by the field plate effect.

### Embodiment 6

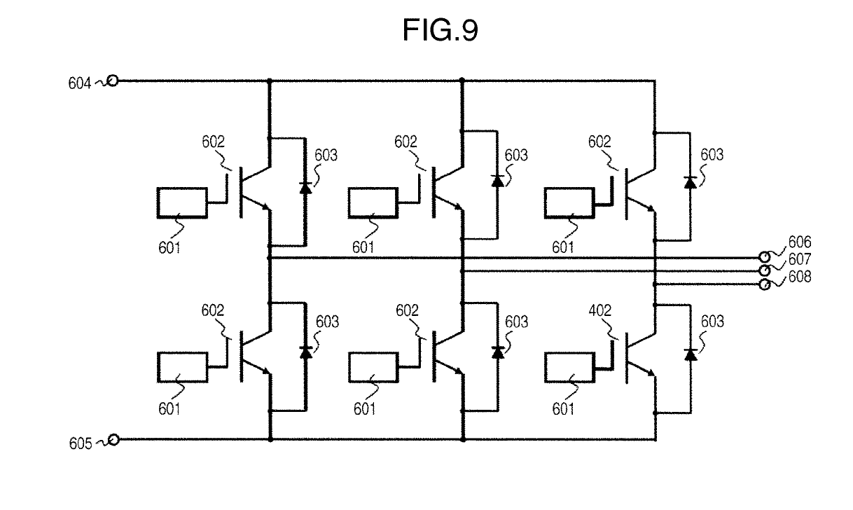

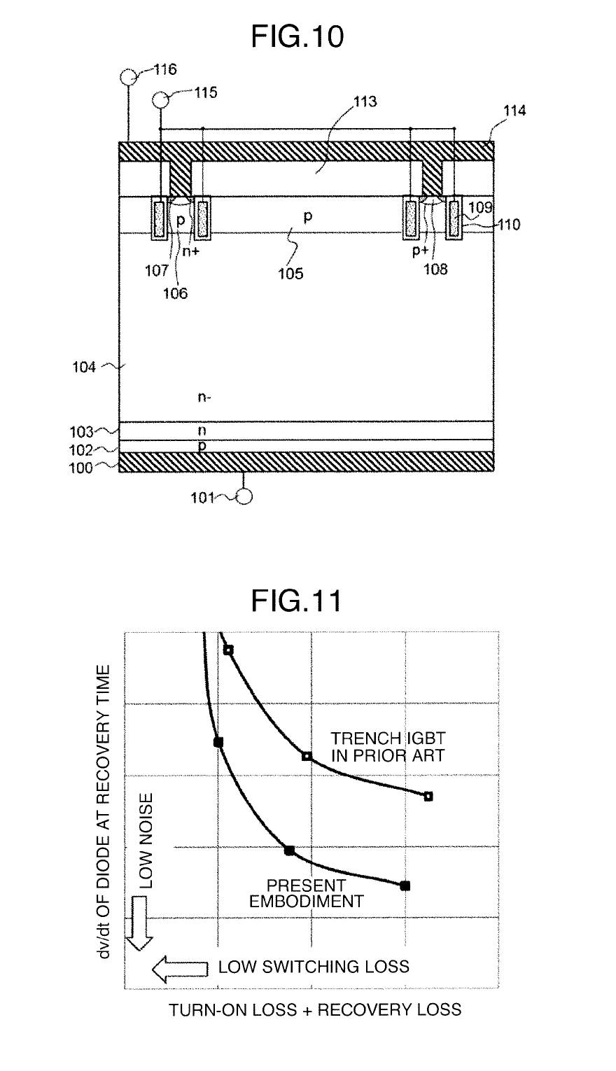

FIG. 9 illustrates a power conversion device where the IGBTs for which the present invention is carried out are used as semiconductor switching elements. The present power conversion device includes a three-phase inverter circuit. A diode 603 is connected to each of the IGBTs 602 in reversely-parallel thereto. Any one of the above-described respective embodiments and modified example is used as these IGBTs.

A half-bridge circuit by the amount of one phase is formed by connecting two IGBTs in series with each other, accordingly, by connecting two reversely-parallel circuits of the IGBT and the diode in series therewith. The half-bridge circuit is formed by the amount of the number of AC phases, i.e., by the amount of the three phases in the present embodiment. An in-series connection point of the two IGBTs, i.e., an in-series connection point of the two reversely-parallel circuits is connected to each of AC outputs 606, 607, ad 608. Collectors of the three IGBTs on the upper-arm side are connected in common with each other, then being connected to a DC terminal 604 on the high-voltage side. Also, emitters of the three IGBTs on the lower-arm side are connected in common therewith, then being connected to a DC terminal 605 on the low-voltage side.

The present power conversion device performs the on/off switching of each IGBT by a gate driving circuit 601, thereby converting DC power to AC power, or converting AC power to DC power.

The above-described respective embodiments and modified example allow the implementation of an enhancement in the controllability of dv/dt by the gate driving circuit during the turn-on switching time-period. This reduces the power loss that accompanies the switching of each IGBT, thereby allowing the low-loss implementation of the power conversion device. This also reduces the noise that occurs in accompaniment with the switching of each IGBT, thereby allowing prevention of the malfunction of the power conversion device, and allowing an enhancement in the reliability of the power conversion device.

The IGBTs explained in the above-described respective embodiments and modified example are the n-channel-type IGBTs. The present invention, however, can be carried out not only for the n-channel-type IGBTs, but also for p-channel-type IGBTs.

The above-described description has been given in accompaniment with the embodiments. It is apparent for those who are skilled in the art, however, that the present invention is not limited thereto, and that a variety of modifications and amendments can be made within the spirit of the present invention and the scope of the appended claims.

### REFERENCE SIGNS LIST

100 collector electrode
101 collector terminal
102 p collector layer
103 n buffer layer
104 n⁻ drift layer
105 floating p layer
106 p channel layer
107 n⁺ emitter layer
108 p⁺ contact layers
109 gate electrode
110 gate insulating film
111 n layer
112 p layer
113 inter-layer insulating film
114 emitter electrode
115 gate terminal
116 collector terminal
117 trench gate
118 gate group
120 trench groove
121 side-wall gate electrode
122 oxide film
200 photoresist
601 gate driving circuit
602 IGBT
603 diode
604, 605 DC terminals
606, 607, 608 AC terminals

1. A semiconductor device, comprising:
a first semiconductor layer of first conduction type;
a second semiconductor layer of second conduction type, the second semiconductor layer adjoining to the first semiconductor layer;
a plurality of third semiconductor layers of the first conduction type, the third semiconductor layers adjoining to the second semiconductor layer;
a plurality of fourth semiconductor layers of the second conduction type, the fourth semiconductor layers being provided on the surfaces of the third semiconductor layers;
a plurality of trench gates provided inside a plurality of trenches, the side walls of the trenches being the surfaces of the third semiconductor layers;
a first main electrode electrically connected to the first semiconductor layer; and
a second main electrode electrically connected to the plurality of third semiconductor layers and the plurality of fourth semiconductor layers, wherein
there are provided a plurality of trench-gate groups, each of the trench-gate groups including the three or more trench gates that adjoin to each other,
the spacing between the two trench-gate groups that adjoin to each other being wider than the spacing between the two trench gates that adjoin to each other in the one trench-gate group.

2. The semiconductor device according to claim 1, wherein
the fourth semiconductor layers are provided on the surfaces of the third semiconductor layers to which the trench gates positioned at end portions of each of the trench-gate groups are opposed.

3. The semiconductor device according to claim 1, wherein
a floating fifth semiconductor layer of the second conduction type is provided between the trench-gate groups that adjoin to each other.

4. The semiconductor device according to claim 3, wherein
the fifth semiconductor layer is formed in such a manner as being deeper than the third semiconductor layers.

5. The semiconductor device according to claim 4, wherein
a partial portion of the second semiconductor layer intervenes between the fifth semiconductor layer and the trench gate.

6. The semiconductor device according to claim 1, wherein
a sixth semiconductor layer of the second conduction type is provided between the third semiconductor layers and the second semiconductor layer, the impurity concentration of the sixth semiconductor layer being higher than that of the second semiconductor layer.

7. The semiconductor device according to claim 6, wherein
a seventh semiconductor layer of the first conduction type is provided between the sixth semiconductor layer and the second semiconductor layer.

8. The semiconductor device according to claim 1, wherein
the plurality of trenches include
a first trench in which the trench gate positioned in the central portion of each of the trench-gate groups is formed; and
a second trench in which the trench gates positioned at end portions of each of the trench-gate groups are formed, the second trench being positioned between the two trench-gate groups that adjoin to each other,
the side walls of the second trench being the surfaces of the third semiconductor layers positioned at the end portions, and the bottom surface of the second trench being the surface of the second semiconductor layer, the width of the second trench being wider than the width of the first trench,
the trench gates positioned at the end portions of each of the trench-gate groups being opposed to the side walls.

9. A power conversion device, comprising:
a pair of DC terminals;
a plurality of in-series connection circuits connected to each other between the DC terminals, a plurality of semiconductor switching elements being connected to the plurality of in-series connection circuits in series with each other; and
a plurality of AC terminals connected to respective in-series connection points of the plurality of in-series connection circuits, wherein
power conversion is performed by the plurality of semiconductor switching elements' performing on/off switchings,
each of the plurality of semiconductor switching elements being the semiconductor device according to claim 1.
